(19) United States
(12) Patent Application Publication
(10) Pub. No.: US 2010/0237500 A1
(43) Pub. Date: Sep. 23, 2010

(54) Semiconductor Substrate and Method of Forming Conformal Solder Wet-Enhancement Layer on Bump-on-Lead Site

(75) Inventors: ChoongHwan Kwon, Seoul (KR); SooMoon Park, Kyonggi-do (KR); HeeJo Chi, Daejeon-si (KR)

Correspondence Address: Robert D. Atkins, 605 W. Knox Road, Suite 104, Tempe, AZ, 85284, US

(73) Assignee: STATS CHIPPAC, LTD., Singapore (SG)

(21) Appl. No.: 12/407,949

(22) Filed: Mar. 20, 2009

(51) Int. Cl. H01L 23/48; H01L 21/768

(52) U.S. Cl. 257/750; 438/612; 257/E23.01; 257/E21.59

(57) ABSTRACT

A semiconductor substrate includes a first conductive layer formed over the semiconductor substrate. The first conductive layer has first and second portions which are electrically isolated during formation of the first conductive layer. A solder resist layer is formed over the first conductive layer and semiconductor substrate. An opening is formed in the solder resist layer to expose the first conductive layer. A seed layer is formed over the semiconductor substrate and first conductive layer within the opening. A second conductive layer is formed over the seed layer within the opening. The opening may expose the second portion of the first conductive layer due to solder resist registration shifting causing a defect condition. The second conductive layer electrically contacts the first and second portions of the first conductive layer. By testing the first and second portions of the first conductive layer, the defect condition can be identified.

### FIELD OF THE INVENTION

The present invention relates in general to semiconductor devices and, more particularly, to a semiconductor substrate and method of forming conformal solder wet-enhancement layer on a bump-on-lead site.

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as high-speed calculations, transmitting and receiving electromagnetic signals, controlling electronic devices, transforming sunlight to electricity, and creating visual projections for television displays. Semiconductor devices are found in the fields of entertainment, communications, power generation, networks, computers, and consumer products. Semiconductor devices are also found in electronic products including military, aviation, automotive, industrial controllers, and office equipment.

Semiconductor devices exploit the electrical properties of semiconductor materials. The atomic structure of semiconductor material allows its electrical conductivity to be manipulated by the application of an electric field or through the process of doping. Doping introduces impurities into the semiconductor material to manipulate and control the conductivity of the semiconductor device.

A semiconductor device contains active and passive electrical structures. Active structures, including transistors, control the flow of electrical current. By varying levels of doping and application of an electric field, the transistor either promotes or restricts the flow of electrical current. Passive structures, including resistors, diodes, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each die is typically identical and contains circuits formed by electrically connecting active and passive components. Back-end manufacturing involves singulating individual die from the finished wafer and packaging the die to provide structural support and environmental isolation.

One goal of semiconductor manufacturing is to produce smaller semiconductor devices. Smaller devices typically consume less power, have higher performance, and can be produced more efficiently. In addition, smaller semiconductor devices have a smaller footprint, which is desirable for smaller end products. A smaller die size may be achieved by improvements in the front-end process resulting in die with smaller, higher density active and passive components. Back-end processes may result in semiconductor device packages with a smaller footprint by improvements in electrical interconnection and packaging materials.

Semiconductor die are commonly mounted to a printed circuit board (PCB) with an interconnect structure such as solder bumps. FIG. 1a show PCB 2 with a bismaleimide triazine-epoxy (BT) layer 3 used to absorb moisture during shipping and storage at the end user site. An electrically conductive layer 4 is formed on PCB 2 as individual signal leads or traces 4a-4c. Traces 4a-4c are electrically isolated with respect to each other when formed. A solder resist layer 5 is formed over BT layer 3 and conductive layer 4. An opening or window 6 is formed in solder resist layer 5 by exposing, curing, and etching the solder resist. The opening 6 exposes conductive layer 4b as a bonding site to a bond-on-lead (BOL) connection to conductive layer 4.

Depending on the pitch between traces 4a-4c and alignment tolerance of opening 6, it is possible for the opening to shift (known as solder resist registration shifting) and cause unintentional exposure of adjacent traces. For example, trace 4a is exposed in opening 6 due to solder resist registration shifting. FIG. 1b shows a top view of the BOL connection site with trace 4a (unintended) and trace 4b (intended) exposed in opening 6.

FIG. 1c shows a semiconductor die 7 with solder bump 8 formed on contact pad 9. When solder bump 8 of semiconductor die 7 is reflowed to mate with trace 4b, the solder material will likely also electrically contact trace 4a, as well as trace 4b, and create an electrical short. The undesired electrical connection between solder bump 8 and trace 4a is a defect in the product, which can go undetected until final assembly testing. The late detection of the defect is costly and lowers final manufacturing yield.

In addition, voids can form under the solder bump in BOL connection sites, particularly for solder bumps having low stand-off height. The voids can reduce product reliability.

### SUMMARY OF THE INVENTION

A need exists to detect electrical shorts in BOL connection sites. Accordingly, in one embodiment, the present invention is a method of manufacturing a semiconductor substrate comprising the step of forming a first conductive layer over a top surface of the semiconductor substrate. The first conductive layer has first and second portions which are electrically isolated during formation of the first conductive layer. The method further includes the steps of forming a solder resist layer over the first conductive layer and semiconductor substrate, forming an opening in the solder resist layer to expose the first portion of the first conductive layer, forming a protective mask over the solder resist layer outside the opening in the solder resist layer, forming a seed layer over the semiconductor substrate and first portion of the first conductive layer within the opening in the solder resist layer, forming a second conductive layer over the seed layer within the opening in the solder resist layer, and removing the protective mask.

In another embodiment, the present invention is a method of manufacturing a semiconductor substrate comprising the step of forming a first conductive layer over a top surface of the semiconductor substrate. The first conductive layer has first and second portions which are electrically isolated during formation of the first conductive layer. The method further includes the steps of forming an insulating layer over the first conductive layer and semiconductor substrate, forming an opening in the insulating layer to expose the first portion of the first conductive layer, and forming a second conductive layer within the opening in the insulating layer.

In another embodiment, the present invention is a method of manufacturing a semiconductor substrate comprising the step of forming a first conductive layer over a top surface of the semiconductor substrate. The first conductive layer has first and second portions which are electrically isolated during formation of the first conductive layer. The method further includes the steps of forming an insulating layer over the first conductive layer and semiconductor substrate, and forming a bond-on-lead site in the insulating layer. The bond-on-lead site includes an opening in the insulating layer to expose a first conductive layer. The method further includes the step of forming a second conductive layer over the opening in the insulating layer.

In another embodiment, the present invention is a semiconductor substrate comprising a first conductive layer formed over a top surface of the semiconductor substrate. An insulating layer is formed over the first conductive layer and semiconductor substrate. A bond-on-lead site is formed in the insulating layer. The bond-on-lead site includes an opening in the insulating layer to expose the first conductive layer. A second conductive layer is formed over the opening in the insulating layer and first conductive layer.

### BRIEF DESCRIPTION OF THE DRAWINGS

FIGS. 1a-1c illustrate a conventional bump-on-lead site for a printed circuit board;

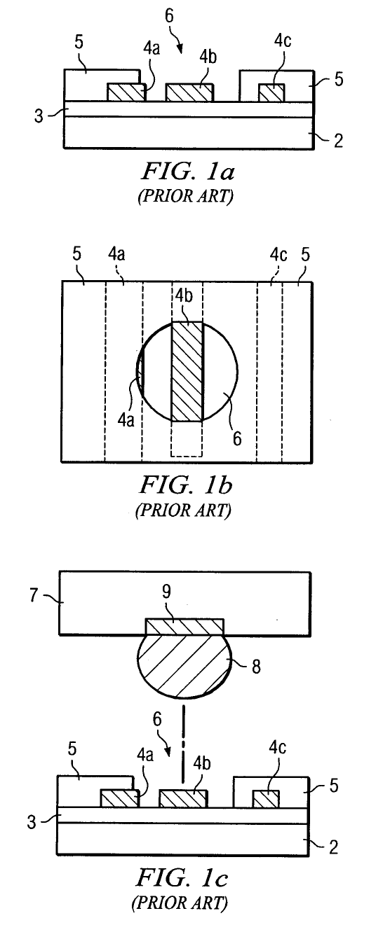

FIG. 2 illustrates the PCB with different types of packages mounted to its surface;

FIGS. 3a-3c illustrate further detail of the representative semiconductor packages mounted to the PCB;

FIG. 4 illustrates a semiconductor die with solder bump mounted to a BOL site of a PCB;

FIGS. 5a-5f illustrate forming a conformal solder wet-enhancement layer over the BOL site; and

FIGS. 6a-6f illustrate detecting a defect in the BOL site using the conformal solder wet-enhancement layer.

### DETAILED DESCRIPTION OF THE DRAWINGS

The present invention is described in one or more embodiments in the following description with reference to the Figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors, have the ability to control the flow of electrical current. Passive electrical components, such as capacitors, inductors, resistors, and transformers, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into a permanent insulator, permanent conductor, or changing the semiconductor material conductivity in response to an electric field. Transistors contain regions of varying types and degrees of doping arranged as necessary to enable the transistor to promote or restrict the flow of electrical current upon the application of an electric field.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist is removed, leaving behind a patterned layer. Alternatively, some types of materials are patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface is required to produce smaller and more densely packed active and passive components. Planarization can be used to remove material from the surface of the wafer and produce a uniformly flat surface. Planarization involves polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer is singulated using a laser cutting device or saw blade. After singulation, the individual die are mounted to a package substrate that includes pins or contact pads for interconnection with other system components. Contact pads formed over the semiconductor die are then connected to contact pads within the package. The electrical connections can be made with solder bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

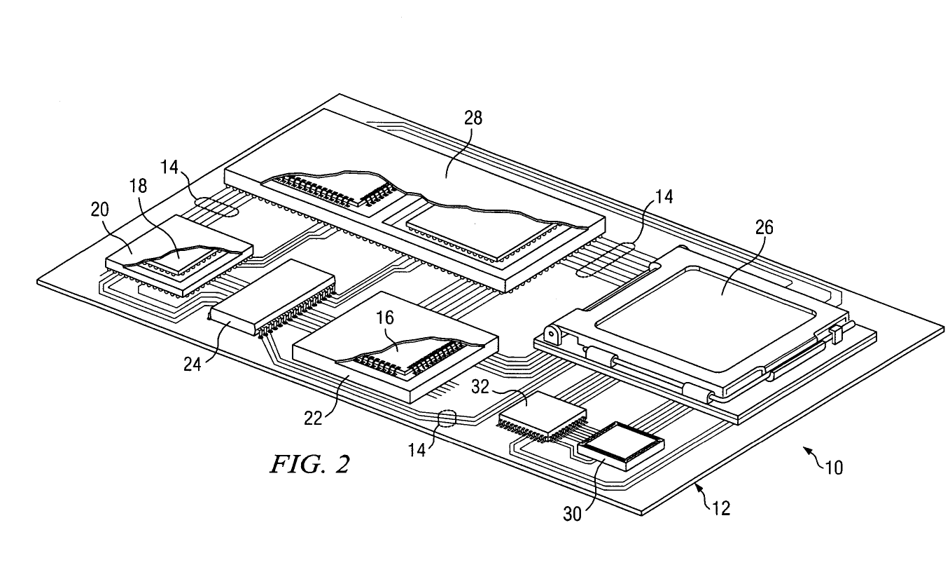

FIG. 2 illustrates electronic device 10 having a chip carrier substrate or printed circuit board (PCB) 12 with a plurality of semiconductor packages mounted on its surface. Electronic device 10 may have one type of semiconductor package, or multiple types of semiconductor packages, depending on the application. The different types of semiconductor packages are shown in FIG. 2 for purposes of illustration.

Electronic device 10 may be a stand-alone system that uses the semiconductor packages to perform an electrical function. Alternatively, electronic device 10 may be a subcomponent of a larger system. For example, electronic device 10 may be a graphics card, network interface card, or other signal processing card that can be inserted into a computer. The semiconductor package can include microprocessors, memories, application specific integrated circuits (ASICs), logic circuits, analog circuits, RF circuits, discrete devices, or other semiconductor die or electrical components.

In FIG. 2, PCB 12 provides a general substrate for structural support and electrical interconnect of the semiconductor packages mounted on the PCB. Conductive signal traces 14 are formed over a surface or within layers of PCB 12 using evaporation, electrolytic plating, electroless plating, screen printing, PVD, or other suitable metal deposition process. Signal traces 14 provide for electrical communication between each of the semiconductor packages, mounted components, and other external system components. Traces 14 also provide power and ground connections to each of the semiconductor packages.

In some embodiments, a semiconductor device has two packaging levels. First level packaging is a technique for mechanically and electrically attaching the semiconductor die to a carrier. Second level packaging involves mechanically and electrically attaching the carrier to the PCB. In other embodiments, a semiconductor device may only have the first level packaging where the die is mechanically and electrically mounted directly to the PCB.

For the purpose of illustration, several types of first level packaging, including wire bond package 16 and flip chip 18, are shown on PCB 12. Additionally, several types of second level packaging, including ball grid array (BGA) 20, bump chip carrier (BCC) 22, dual in-line package (DIP) 24, land grid array (LGA) 26, multi-chip module (MCM) 28, quad flat non-leaded package (QFN) 30, and quad flat package 32, are shown mounted on PCB 12. Depending upon the system requirements, any combination of semiconductor packages, configured with any combination of first and second level packaging styles, as well as other electronic components, can be connected to PCB 12. In some embodiments, electronic device 10 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using cheaper components and a streamlined manufacturing process. The resulting devices are less likely to fail and less expensive to manufacture resulting in lower costs for consumers.

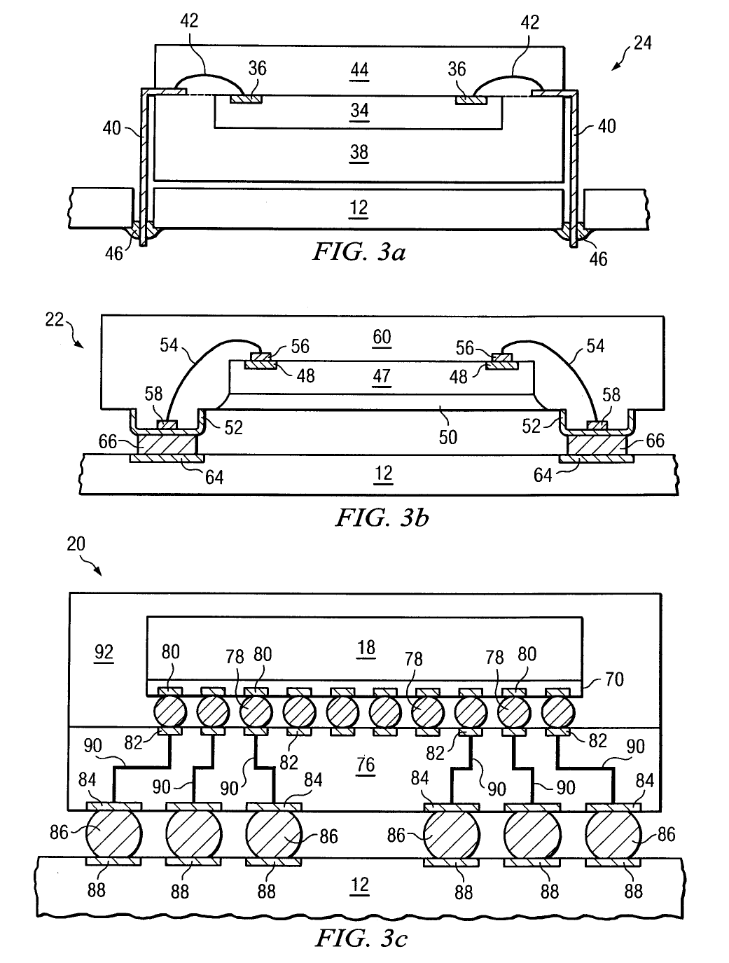

FIG. 3a illustrates further detail of DIP 24 mounted on PCB 12. DIP 24 includes semiconductor die 34 having contact pads 36. Semiconductor die 34 includes an active region containing analog or digital circuits implemented as active devices, passive devices, conductive layers, and dielectric layers formed within semiconductor die 34 and are electrically interconnected according to the electrical design of the die. For example, the circuit may include one or more transistors, diodes, inductors, capacitors, resistors, and other circuit elements formed within the active region of die 34. Contact pads 36 are made with a conductive material, such as aluminum (Al), copper (Cu), tin (Sn), nickel (Ni), gold (Au), or silver (Ag), and are electrically connected to the circuit elements formed within die 34. Contact pads 36 are formed by PVD, CVD, electrolytic plating, or electroless plating process. During assembly of DIP 24, semiconductor die 34 is mounted to a carrier 38 using a gold-silicon eutectic layer or adhesive material such as thermal epoxy. The package body includes an insulative packaging material such as polymer or ceramic. Conductor leads 40 are connected to carrier 38 and wire bonds 42 are formed between leads 40 and contact pads 36 of die 34 as a first level packaging. Encapsulant 44 is deposited over the package for environmental protection by preventing moisture and particles from entering the package and contaminating die 34, contact pads 36, or wire bonds 42. DIP 24 is connected to PCB 12 by inserting leads 40 into holes formed through PCB 12. Solder material 46 is flowed around leads 40 and into the holes to physically and electrically connect DIP 24 to PCB 12. Solder material 46 can be any metal or electrically conductive material, e.g., Sn, lead (Pb), Au, Ag, Cu, zinc (Zn), bismuthinite (Bi), and alloys thereof, with an optional flux material. For example, the solder material can be eutectic Sn/Pb, high-lead, or lead-free.

FIG. 3b illustrates further detail of BCC 22 mounted on PCB 12. Semiconductor die 47 is connected to a carrier by wire bond style first level packaging. BCC 22 is mounted to PCB 12 with a BCC style second level packaging. Semiconductor die 47 having contact pads 48 is mounted over a carrier using an underfill or epoxy-resin adhesive material 50. Semiconductor die 47 includes an active region containing analog or digital circuits implemented as active devices, passive devices, conductive layers, and dielectric layers formed within semiconductor die 47 and are electrically interconnected according to the electrical design of the die. For example, the circuit may include one or more transistors, diodes, inductors, capacitors, resistors, and other circuit elements formed within the active region of die 47. Contact pads 48 are made with a conductive material, such as Al, Cu, Sn, Ni, Au, or Ag, and are electrically connected to the circuit elements formed within die 47. Contact pads 48 are formed by PVD, CVD, electrolytic plating, or electroless plating process. Wire bonds 54 and bond pads 56 and 58 electrically connect contact pads 48 of semiconductor die 47 to contact pads 52 of BCC 22 forming the first level packaging. Molding compound or encapsulant 60 is deposited over semiconductor die 47, wire bonds 54, contact pads 48, and contact pads 52 to provide physical support and electrical isolation for the device. Contact pads 64 are formed over a surface of PCB 12 using evaporation, electrolytic plating, electroless plating, screen printing, PVD, or other suitable metal deposition process and are typically plated to prevent oxidation. Contact pads 64 electrically connect to one or more conductive signal traces 14. Solder material is deposited between contact pads 52 of BCC 22 and contact pads 64 of PCB 12. The solder material is reflowed to form bumps 66 which form a mechanical and electrical connection between BCC 22 and PCB 12.

In FIG. 3c, semiconductor die 18 is mounted face down to carrier 76 with a flip chip style first level packaging. BGA 20 is attached to PCB 12 with a BGA style second level packaging. Active region 70 containing analog or digital circuits implemented as active devices, passive devices, conductive layers, and dielectric layers formed within semiconductor die 18 is electrically interconnected according to the electrical design of the die. For example, the circuit may include one or more transistors, diodes, inductors, capacitors, resistors, and other circuit elements formed within active region 70 of semiconductor die 18. Semiconductor die 18 is electrically and mechanically attached to carrier 76 through a large number of individual conductive solder bumps or balls 78. Solder bumps 78 are formed over bump pads or interconnect sites 80, which are disposed on active region 70. Bump pads 80 are made with a conductive material, such as Al, Cu, Sn, Ni, Au, or Ag, and are electrically connected to the circuit elements formed in active region 70. Bump pads 80 are formed by PVD, CVD, electrolytic plating, or electroless plating process. Solder bumps 78 are electrically and mechanically connected to contact pads or interconnect sites 82 on carrier 76 by a solder reflow process.

BGA 20 is electrically and mechanically attached to PCB 12 by a large number of individual conductive solder bumps or balls 86. The solder bumps are formed over bump pads or interconnect sites 84. The bump pads 84 are electrically connected to interconnect sites 82 through conductive lines 90 routed through carrier 76. Contact pads 88 are formed over a surface of PCB 12 using evaporation, electrolytic plating, electroless plating, screen printing, PVD, or other suitable metal deposition process and are typically plated to prevent oxidation. Contact pads 88 electrically connect to one or more conductive signal traces 14. The solder bumps 86 are electrically and mechanically connected to contact pads or bonding pads 88 on PCB 12 by a solder reflow process. Molding compound or encapsulant 92 is deposited over semiconductor die 18 and carrier 76 to provide physical support and electrical isolation for the device. The flip chip semiconductor device provides a short electrical conduction path from the active devices on semiconductor die 18 to conduction tracks on PCB 12 in order to reduce signal propagation distance, lower capacitance, and improve overall circuit performance. In another embodiment, the semiconductor die 18 can be mechanically and electrically attached directly to PCB 12 using flip chip style first level packaging without carrier 76.

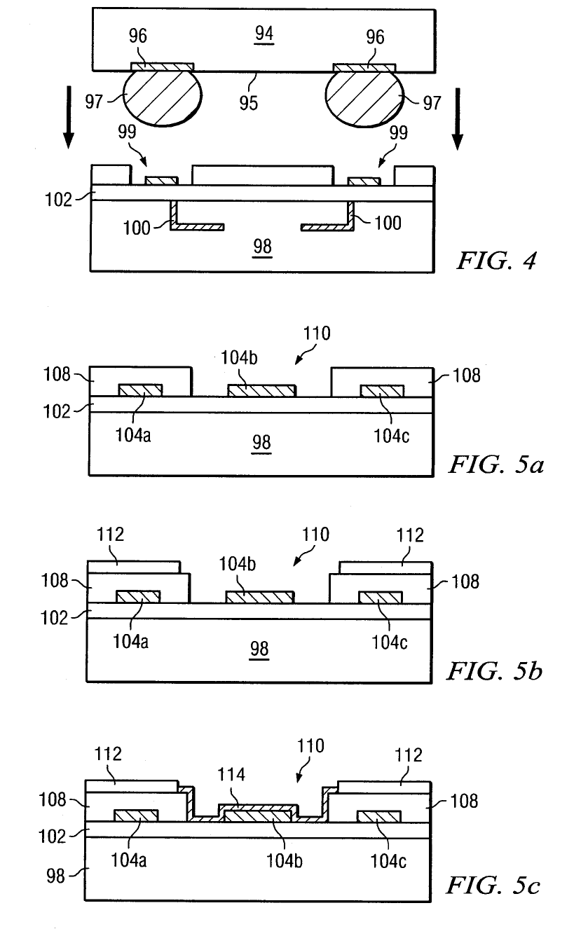

FIG. 4 shows a semiconductor die 94 including analog or digital circuits implemented as active and passive devices, conductive layers, and dielectric layers formed over active surface 95 and electrically interconnected according to the electrical design and function of the die. For example, the circuit may include one or more transistors, diodes, and other circuit elements formed within active surface 95 to implement baseband digital circuits, such as digital signal processor (DSP), memory, or other signal processing circuit. Semiconductor die 94 may also contain integrated passive devices (IPD), such as inductors, capacitors, and resistors, for radio frequency (RF) signal processing. Contact pads 96 electrically connect to active and passive devices and signal traces within active surface 95 of semiconductor die 94. Solder bumps 97 are formed on contact pads 96 of semiconductor die 94.

Semiconductor substrate 98 includes bump-on-lead (BOL) connection sites 99. In one embodiment, semiconductor substrate 98 is a PCB. A bismaleimide triazine-epoxy (BT) layer 102 is formed on the surface of semiconductor substrate 98. BT layer 102 absorbs moisture during shipping and storage at the end user site. Semiconductor die 94 is mounted to semiconductor substrate 98. Solder bumps 97 are reflowed to electrically connect contact pads 96 to BOL sites 99. BOL sites 99 connect through conductive layers 100 in semiconductor substrate 98 to send and receive electrical signals to other components.

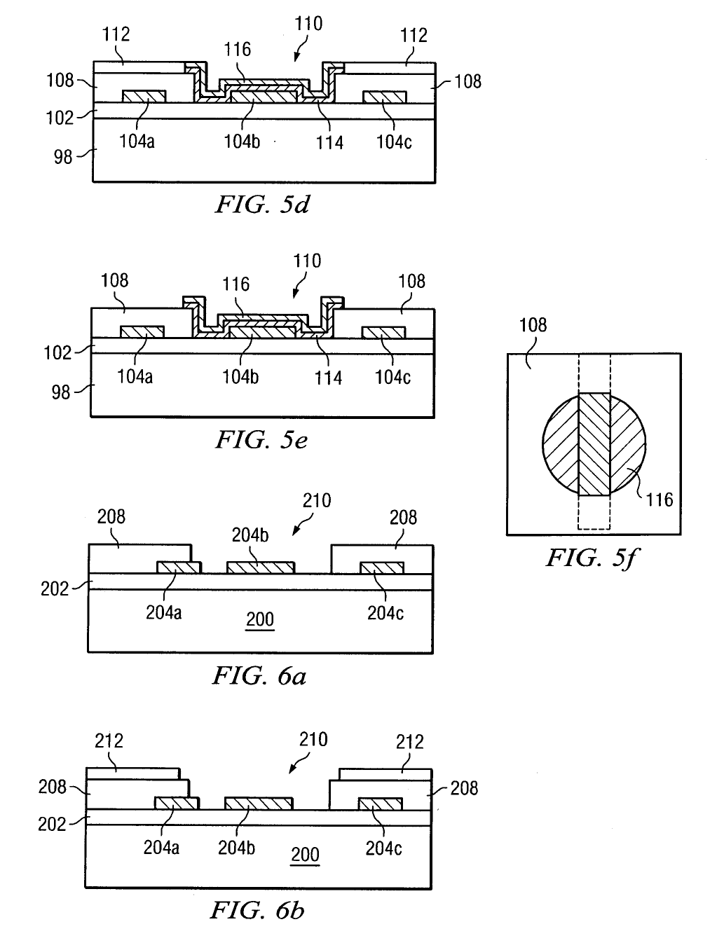

FIG. 5a shows further detail of semiconductor substrate 98 with a BT layer 102 formed on its surface and BOL site 99. An electrically conductive layer 104 is formed over BT layer 102 using a patterning and deposition process. Conductive layer 104 is formed using PVD, CVD, electrolytic plating, electroless plating process, or other suitable metal deposition process. Conductive layer 104 can be one or more layers of Al, Cu, Sn, Ni, Au, Ag, or other suitable electrically conductive material. Conductive layer 104 constitutes a plurality of signal leads or traces 104a-104c running through semiconductor substrate 98 to make electrical connection to other components. Traces 104a-104c are electrically isolated with respect to each other when formed.

An insulating layer 108 is formed over BT layer 102 and conductive layer 104. In one embodiment insulating layer 108 is a solder resist layer. An opening or window 110 is formed in insulating layer 108 by exposing, curing, and etching the insulating layer. The opening 110 exposes trace 104b in forming BOL connection site 99. In this case, only trace 104b is exposed in opening 110. The solder resist registration has proper alignment so that traces 104a and 104c are covered by insulating layer 108.

In FIG. 5b, a protection mask 112 is attached to the cured insulating layer 108. A seed layer 114 is conformally formed on the portions of BT layer 102, conductive layer 104, and sidewalls of insulating layer 108 exposed by opening 110, as shown in FIG. 5c. Seed layer 114 can be palladium (Pd) or similar material formed by electroless plating. Protection mask 112 prevents formation of seed layer 114 over the portion of insulating layer 108 outside opening 110, which could damage the insulating layer.

In FIG. 5d, an electrically conductive layer 116 is conformally formed over seed layer 114 using a patterning and deposition process. In one embodiment, conductive layer 116 is electro-plated Cu. Alternatively, conductive layer 116 is formed using PVD, CVD, electrolytic plating, electroless plating process, or other suitable metal deposition process. Conductive layer 104 can also include one or more layers of electroless nickel immersion gold (ENIG), electroless nickel electroless palladium immersion gold (ENEPIG), organic solderability preservative (OSP), immersion tin (IT), immersion gold (IG), Al, Sn, Ni, Au, Ag, or other suitable electrically conductive material. Protective mask 112 is removed in FIG. 5e by a wet or dry etching process.

FIG. 5f shows a top view of conductive layer 116 formed over BOL connection site 99. Conductive layer 116, as formed over the portions of BT layer 102, conductive layer 104, and sidewalls of insulating layer 108 exposed by opening 110, constitutes a conformal solder wet-enhancement layer which provides better wettability for the solder bump due to increased metal contact area. The conformal solder wet-enhancement layer reduces voids under the solder bump in BOL connection sites.

Conductive layer 116 also provides the ability to test for exposed adjacent traces in opening 110. If an adjacent trace was exposed in opening 110 due to solder resist registration shifting, then conductive layer 116 would electrically contact the adjacent trace. An electrical continuity test or other functional test between trace 104b and the exposed adjacent trace would indicate the electrical short, which is a test failure. In the present example of FIGS. 5a-5f, since no trace adjacent to trace 104b is exposed in opening 110. Conductive layer 116 electrically contacts only trace 104b. The continuity test passes as traces 104a-104c each continue to be electrically isolated with respect to each other. The BOL connection site 99 is considered good and semiconductor substrate 98 continues on to subsequent manufacturing steps. The conformal solder wet-enhancement layer 116 also reduces voids under the solder bump in BOL connection site, particularly for solder bumps having low stand-off height.

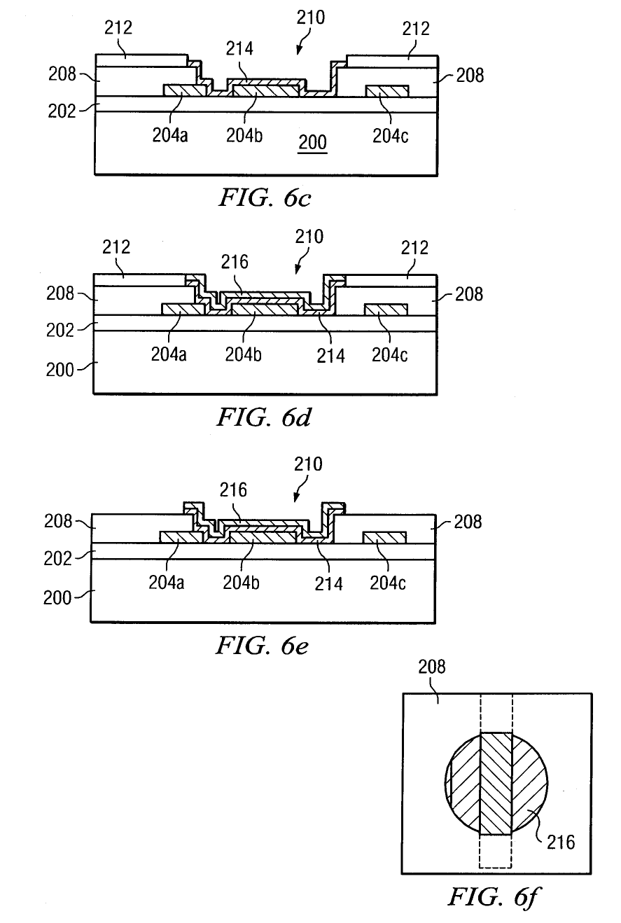

Another BOL site case is shown in FIGS. 6a-6f. FIG. 6a shows a semiconductor substrate 200 with BT layer 202 formed on its surface. In one embodiment, semiconductor substrate 200 is a PCB. BT layer 202 absorbs moisture during shipping and storage at the end user site. An electrically conductive layer 204 is formed over BT layer 202 using a patterning and deposition process. Conductive layer 204 is formed using PVD, CVD, electrolytic plating, electroless plating process, or other suitable metal deposition process. Conductive layer 204 can be one or more layers of Al, Cu, Sn, Ni, Au, Ag, or other suitable electrically conductive material. Conductive layer 204 constitutes a plurality of signal leads or traces 204a-204c to make electrical connection to other components. Traces 204a-204c are electrically isolated with respect to each other when formed.

An insulating layer 208 is formed over BT layer 202 and conductive layer 204. In one embodiment, insulating layer 208 is a solder resist layer. An opening or window 210 is formed in insulating layer 208 by exposing, curing, and etching the insulating layer. The opening 210 exposes trace 204b in forming the BOL connection site. In this case, due to a small pitch between traces 204a-204c and alignment tolerance of opening 210, solder resist registration shifting has caused adjacent trace 204a to be exposed within opening 210. Trace 204c is covered by insulating layer 208.

In FIG. 6b, a protection mask 212 is attached to the cured insulating layer 208. A seed layer 214 is conformally formed on the portions of BT layer 202, conductive layer 204, and sidewalls of insulating layer 208 exposed by opening 210, as shown in FIG. 6c. Seed layer 214 can be Pd or similar material formed by electroless plating. Protection mask 212 prevents formation of seed layer 214 over the portion of insulating layer 208 outside opening 210, which could damage the insulating layer.

In FIG. 6d, an electrically conductive layer 216 is conformally formed over seed layer 214 using a patterning and deposition process. In one embodiment, conductive layer 216 is electro-plated Cu. Alternatively, conductive layer 216 is formed using PVD, CVD, electrolytic plating, electroless plating process, or other suitable metal deposition process. Conductive layer 204 can also include one or more layers of ENIG, ENEPIG, IT, IG, Al, Sn, Ni, Au, Ag, or other suitable electrically conductive material. Protective mask 212 is removed in FIG. 6e by a wet or dry etching process.

FIG. 6f shows a top view of conductive layer 216 formed over the BOL connection site. Conductive layer 216, as formed over the portions of BT layer 202, conductive layer 204, and sidewalls of insulating layer 208 exposed by opening 210, constitutes a conformal solder wet-enhancement layer which provides better wettability for the solder bump due to increased metal contact area. The conformal solder wet-enhancement layer reduces voids under the solder bump in BOL connection sites.

Conductive layer 216 also provides the ability to test for exposed adjacent traces in opening 210. In this case, trace 204b, as well as adjacent trace 204a, are exposed in opening 210 due to solder resist registration shifting. Conductive layer 216 electrically contacts both traces 204a and 204b to electrically short the traces together. An electrical continuity test or other functional test between trace 204a and 204b will indicate the electrical short between traces 204a and 204b, which is a test failure. The BOL connection site is considered defective and the assembly can be rejected or repaired prior to final assembly manufacturing steps. A test failure of semiconductor substrate 200 is less costly than a test failure of the final package with the semiconductor die mounted. The solder wet-enhancement layer 116 saves time and cost, increases final yield, and reduces voids under the solder bump in BOL connection site, particularly for solder bumps having low stand-off height.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of manufacturing a semiconductor substrate, comprising:
forming a first conductive layer over a top surface of the semiconductor substrate, the first conductive layer having first and second portions which are electrically isolated during formation of the first conductive layer;
forming a solder resist layer over the first conductive layer and semiconductor substrate;
forming an opening in the solder resist layer to expose the first portion of the first conductive layer;
forming a protective mask over the solder resist layer outside the opening in the solder resist layer;
forming a seed layer over the semiconductor substrate and first portion of the first conductive layer within the opening in the solder resist layer;
forming a second conductive layer over the seed layer within the opening in the solder resist layer; and
removing the protective mask.

2. The method of claim 1, wherein forming the opening in the solder resist layer exposes the second portion of the first conductive layer due to solder resist registration shifting causing a defect condition, the second conductive layer electrically contacting the first and second portions of the first conductive layer.

3. The method of claim 2, further including testing the first and second portions of the first conductive layer to detect the defect condition.

4. The method of claim 1, wherein the semiconductor substrate includes a printed circuit board.

5. A method of manufacturing a semiconductor substrate, comprising:
forming a first conductive layer over a top surface of the semiconductor substrate, the first conductive layer having first and second portions which are electrically isolated during formation of the first conductive layer;
forming an insulating layer over the first conductive layer and semiconductor substrate;
forming an opening in the insulating layer to expose the first portion of the first conductive layer; and
forming a second conductive layer within the opening in the insulating layer.

6. The method of claim 5, further including:
forming a protective mask over the insulating layer outside the opening in the insulating layer prior to forming the second conductive layer;
forming a seed layer over the semiconductor substrate and first portion of the first conductive layer within the opening in the insulating layer; and
removing the protective mask after forming the second conductive layer over the seed layer within the opening in the insulating layer.

7. The method of claim 5, wherein the insulating layer includes a solder resist layer.

8. The method of claim 5, wherein forming the opening in the insulating layer exposes the second portion of the first conductive layer due to registration shifting causing a defect condition, the second conductive layer electrically contacting the first and second portions of the first conductive layer.

9. The method of claim 8, further including testing the first and second portions of the first conductive layer to detect the defect condition.

10. The method of claim 5, wherein the semiconductor substrate includes a printed circuit board.

11. The method of claim 5, further including forming a bismaleimide triazine-epoxy layer over the semiconductor substrate.

12. A method of manufacturing a semiconductor substrate, comprising:
forming a first conductive layer over a top surface of the semiconductor substrate, the first conductive layer having first and second portions which are electrically isolated during formation of the first conductive layer;
forming an insulating layer over the first conductive layer and semiconductor substrate;
forming a bond-on-lead site in the insulating layer, the bond-on-lead site including an opening in the insulating layer to expose a first conductive layer; and
forming a second conductive layer over the opening in the insulating layer.

13. The method of claim 12, further including:
forming a protective mask over the insulating layer outside the opening in the insulating layer prior to forming the second conductive layer;
forming a seed layer over the semiconductor substrate and first portion of the first conductive layer within the opening in the insulating layer; and
removing the protective mask after forming the second conductive layer over the seed layer within the opening in the insulating layer.

14. The method of claim 12, wherein the insulating layer includes a solder resist layer.

15. The method of claim 12, wherein forming the opening in the insulating layer exposes the second portion of the first conductive layer due to registration shifting causing a defect condition, the second conductive layer electrically contacting the first and second portions of the first conductive layer.

16. The method of claim 15, further including testing the first and second portions of the first conductive layer to detect the defect condition.

17. The method of claim 12, wherein the semiconductor substrate includes a printed circuit board.

18. The method of claim 12, further including forming a bismaleimide triazine-epoxy layer over the semiconductor substrate.

19. The method of claim 12, wherein the second conductive layer includes material selected from the group consisting of copper, electroless nickel immersion gold, electroless nickel electroless palladium immersion gold, organic solderability preservative, immersion tin, immersion gold, aluminum, tin, nickel, silver, and gold.

20. A semiconductor substrate, comprising:
a first conductive layer formed over a top surface of the semiconductor substrate;
an insulating layer formed over the first conductive layer and semiconductor substrate;
a bond-on-lead site formed in the insulating layer, the bond-on-lead site including an opening in the insulating layer to expose the first conductive layer; and
a second conductive layer formed over the opening in the insulating layer and first conductive layer.

21. The semiconductor substrate of claim 20, further including a seed layer formed over the semiconductor substrate and first conductive layer within the opening in the insulating layer.

22. The semiconductor substrate of claim 20, wherein the insulating layer includes a solder resist layer.

23. The semiconductor substrate of claim 20, further including a bismaleimide triazine-epoxy layer formed over the semiconductor substrate.

24. The semiconductor substrate of claim 20, wherein the second conductive layer includes material selected from the group consisting of copper, electroless nickel immersion gold, electroless nickel electroless palladium immersion gold, organic solderability preservative, immersion tin, immersion gold, aluminum, tin, nickel, silver, and gold.
